(19) United States
(12) Patent Application Publication
(10) Pub. No.: US 2026/0235653 A1
(43) Pub. Date: Aug. 13, 2026

(54) TEST SYSTEM AND TEST METHOD

(71) Applicant: ANRITSU CORPORATION, Kanagawa (JP)

(72) Inventors: Takeshi KOBAYASHI, Kanagawa (JP); Hirofumi SUGANUMA, Kanagawa (JP)

(21) Appl. No.: 19/421,094

(22) Filed: Dec. 16, 2025

(30) Foreign Application Priority Data
Feb. 13, 2025 (JP) 2025-021316

(51) Int. Cl. G01R 29/08

(52) U.S. Cl. CPC G01R 29/0878; G01R 29/0892

(57) ABSTRACT

A test system includes a singular value decomposition processing unit that performs singular value decomposition on instantaneous characteristics H(k, n_{RS}) into a form of U₀(k, n_{RS})D₀(k, n_{RS})V₀(k, n_{RS})^{H}; a signal conversion unit that converts N_{Tx} parallel test signals, including the CSI-RS transmitted from N_{Tx} transmitting antennas, into R parallel signals by multiplying them by V₀(k, n_{RS})^{H}, a time-domain signal generation unit that generates OFDM modulation signals from the R parallel signals, and a convolution operation unit that performs a convolution operation between the OFDM modulation signals and impulse responses of a product U₀(k, n_{RS})D₀(k, n_{RS}) of U₀(k, n_{RS}) and D₀(k, n_{RS}) to generate N_{Rx} parallel test signals in the time domain that are respectively received by N_{Rx} receiving antennas of a UE.

### TECHNICAL FIELD

The present invention relates to a test system and a test method for reproducing instantaneous characteristics of propagation path characteristics measured in an actual propagation path environment.

### BACKGROUND ART

When testing a mobile phone terminal (User Equipment: UE), demodulation performance in a fading environment is evaluated by supplying a signal passed through a propagation path simulator, where the signal is a downlink signal output from a base station simulator, to the UE. As a channel model used in such a propagation path simulator, a channel model defined for testing is often employed. On the other hand, there is also a demand to evaluate the demodulation performance of a UE using propagation path characteristics close to an actual propagation path environment (including time variations of propagation path characteristics due to the movement of the UE and surrounding objects).

As methods for simulating an actual propagation path environment, for example, methods disclosed in Patent Documents 1 and 2 are known.

The method disclosed in Patent Document 1 simulates a propagation path environment by parameterizing statistical properties of measured propagation path characteristics and converting the statistical properties into a channel model, thereby enabling evaluation of whether the channel model can simulate the propagation path characteristics in the actual propagation path environment with sufficient accuracy.

The method disclosed in Patent Document 2 reduces the circuit scale of a test system by processing propagation path characteristics with a large number of transmitting antennas in the frequency domain.

### RELATED ART DOCUMENT

### Patent Document

[Patent Document 1] JP-A-2024-168749
[Patent Document 2] JP-A-2019-009493

### DISCLOSURE OF THE INVENTION

### Problem that the Invention is to Solve

The method disclosed in Patent Document 1 does not reproduce the instantaneous characteristics of the propagation path characteristics of an actual propagation path. For this reason, propagation path simulation using a channel model such as the Tapped Delay Line (TDL) model in Patent Document 1 can only simulate statistically uniform situations, making it difficult to simulate in a form that includes changes in propagation path characteristics due to the movement of the UE and surrounding objects.

Furthermore, the method disclosed in Patent Document 2 also does not reproduce the instantaneous characteristics of the propagation path characteristics of an actual propagation path, and processes for applying multipath and Doppler frequency shift effects in the frequency domain were complex.

The present invention has been made to solve such conventional problems, and aims to provide a test system and a test method capable of simulating a propagation path environment while suppressing the circuit scale, by using a method that reproduces the instantaneous characteristics of the propagation path characteristics of an actual propagation path.

### Means for Solving the Problem

In order to solve the above-described problems, according to the present invention, there is provided a test system (1) that transmits test signals to a device under test (120) having N_{Rx} receiving antennas, the test system including an actual propagation path characteristic calculation unit (31) that calculates instantaneous characteristics H(k, n_{RS}) of propagation path characteristics of an actual propagation path for each subcarrier fₖ and timing t_{nRS}, using reference signals included in IQ data of a downlink signal output from an antenna device (10) that receives the downlink signal transmitted from N_{Tx} transmitting antennas (Tx #1 to Tx #N_{Tx}) of a network-side transceiver (100) at N_{Rx} receiving antennas (Rx #1 to Rx #N_{Rx}) in an actual propagation path (110) environment, a singular value decomposition processing unit (33) that performs singular value decomposition on the instantaneous characteristics H(k, n_{RS}) into a form of H(k, n_{RS})=U₀(k, n_{RS})D₀(k, n_{RS})V₀(k, n_{RS})^{H}, and calculates an N_{Rx}-row R-column sub-matrix U₀ of a unitary matrix, an R-row R-column diagonal matrix D₀(k, n_{RS}) whose diagonal components are the effective singular values of the instantaneous characteristics H(k, n_{RS}), and a conjugate-transpose matrix V₀(k, n_{RS})^{H} of an N_{Tx}-row R-column sub-matrix V₀(k, n_{RS}) of a unitary matrix, where R is the number of effective singular values, a test signal generation unit (26) that generates a test reference signal transmitted from the N_{Tx} transmitting antennas, a modulation signal of test data to be transmitted to the device under test, and N_{Tx} parallel test signals including the test reference signal in the frequency domain and the modulation signal in the frequency domain, a signal conversion unit (24) that converts the N_{Tx} parallel test signals into R parallel signals by multiplying the N_{Tx} parallel test signals by the conjugate-transpose matrix V₀(k, n_{RS})^{H}; a time-domain signal generation unit (25) that performs inverse Fourier transform processing on the R parallel signals to generate time-domain signals, and a convolution operation unit (41) that performs a convolution operation between the time-domain signals generated by the time-domain signal generation unit and impulse responses of a product U₀(k, n_{RS})D₀(k, n_{RS}) of the sub-matrix U₀(k, n_{RS}) of the unitary matrix and the diagonal matrix D₀(k, n_{RS}) to generate N_{Rx} parallel test signals in the time domain that are respectively received by the N_{Rx} receiving antennas of the device under test.

The above V₀(k, n_{RS}) H is the conjugate transpose (Hermitian transpose) of the matrix V₀(k, n_{RS}). Hereinafter, “A^{H}” represents the conjugate transpose (Hermitian transpose) of a matrix A. Furthermore, for vectors, “a (bold)^{H}” represents the conjugate transpose (Hermitian transpose) of a vector a (bold).

With this configuration, the test system according to the present invention can simulate a propagation path environment while suppressing the circuit scale from the time-domain signal generation unit onward, using a method for reproducing the instantaneous characteristics of the propagation path characteristics of an actual propagation path.

Furthermore, since the test system according to the present invention uses a method for reproducing the instantaneous characteristics of the propagation path characteristics of an actual propagation path, it is possible to simulate propagation path characteristics accompanied by the movement of a UE and surrounding objects.

Moreover, the test system according to the present invention can obtain the effect of reducing the number of antennas in the frequency domain and the effect of multipath and Doppler frequency shift in the time domain, with a simple configuration, by dividing the instantaneous characteristics H(k, n_{RS}) into V₀(k, n_{RS})^{H} and the product U₀(k,n_{RS})D₀(k, n_{RS}), and performing processing in the frequency domain and time domain respectively.

In addition, according to the present invention, there is provided a test system (1) that transmits test signals to a device under test (120) having N_{Rx} receiving antennas, the test system including an actual propagation path characteristic calculation unit (31) that calculates instantaneous characteristics H(k, n_{RS}) of propagation path characteristics of an actual propagation path for each subcarrier fₖ and timing t_{nRS}, using reference signals included in IQ data of a downlink signal output from an antenna device (10) that receives the downlink signal transmitted from N_{Tx} transmitting antennas (Tx #1 to Tx #N_{Tx}) of a network-side transceiver (100) at N_{Rx} receiving antennas (Rx #1 to Rx #N_{Rx}) in an actual propagation path (110) environment, an interpolation processing unit (32) that interpolates the instantaneous characteristics H(k, n_{RS}) in a time axis direction to generate interpolated propagation path characteristics H(k,n) with a sampling rate that satisfies the sampling theorem, a singular value decomposition processing unit (33) that performs singular value decomposition on the interpolated propagation path characteristics H(k,n) into a form of H(k,n)=U₀(k, n)D₀(k, n)V₀(k, n)^{H}, and calculates an N_{Rx}-row R-column sub-matrix U₀ of a unitary matrix, an R-row R-column diagonal matrix D₀(k,n) whose diagonal components are the effective singular values of the interpolated propagation path characteristics H(k,n), and a conjugate-transpose matrix V₀(k, n)^{H} of an N_{Tx}-row R-column sub-matrix V₀(k, n) of a unitary matrix, where R is the number of effective singular values, a test signal generation unit (26) that generates a test reference signal transmitted from the N_{Tx} transmitting antennas, a modulation signal of test data to be transmitted to the device under test, and N_{Tx} parallel test signals including the test reference signal in the frequency domain and the modulation signal in the frequency domain, a signal conversion unit (24) that converts the N_{Tx} parallel test signals into R parallel signals by multiplying the N_{Tx} parallel test signals by the conjugate-transpose matrix V₀(k,n)^{H}; a time-domain signal generation unit (25) that performs inverse Fourier transform processing on the R parallel signals to generate time-domain signals, and a convolution operation unit (41) that performs a convolution operation between the time-domain signals generated by the time-domain signal generation unit and impulse responses of a product U₀(k, n)D₀(k, n) of the sub-matrix U₀(k, n) of the unitary matrix and the diagonal matrix D₀(k,n) to generate N_{Rx} parallel test signals in the time domain that are respectively received by the N_{Rx} receiving antennas of the device under test.

With this configuration, the test system according to the present invention can simulate a propagation path environment while suppressing the circuit scale from the time-domain signal generation unit onward, using a method for reproducing the instantaneous characteristics of the propagation path characteristics of an actual propagation path.

Furthermore, since the test system according to the present invention uses a method for reproducing the instantaneous characteristics of the propagation path characteristics of an actual propagation path, it is possible to simulate propagation path characteristics accompanied by the movement of the UE and surrounding objects.

Furthermore, the test system according to the present invention can obtain the effect of reducing the number of antennas in the frequency domain and the effect of multipath and Doppler frequency shift in the time domain, with a simple configuration, by dividing the interpolated propagation path characteristics H(k,n) into V₀(k, n)^{H} and the product U₀(k, n)D₀(k, n), and performing processing in the frequency domain and time domain respectively.

In addition, the test system according to the present invention may be configured such that the test signal generation unit may include a modulation signal generation unit (21) that generates the modulation signal in the frequency domain, a beamforming processing unit (22) that performs arithmetic processing equivalent to beamforming processing for achieving desired beam characteristics of radio waves of the downlink signal transmitted from the N_{Tx} transmitting antennas, on the modulation signal in the frequency domain to generate N_{Tx} parallel beamforming processed signals, and an integration unit (23) that adds the test reference signal in the frequency domain to each of the N_{Tx} parallel beamforming processed signals to generate the N_{Tx} parallel test signals.

Furthermore, the test system according to the present invention may be configured to further include a propagation path characteristic storage unit (35) that stores impulse responses of the conjugate-transpose matrix V₀(k, n_{RS})^{H} or V₀(k, n)^{H}, and impulse responses of the product U₀(k,n_{RS})D₀(k,n_{RS}) or U₀(k,n)D₀(k,n), in which the signal conversion unit converts the impulse responses of the conjugate-transpose matrix V₀(k, n_{RS})^{H} or V₀(k,n)^{H} read from the propagation path characteristic storage unit back to the conjugate-transpose matrix V₀(k, n_{RS})^{H} or V₀(k,n)^{H} in the frequency domain before multiplying the N_{Tx} parallel test signals by the conjugate-transpose matrix V₀(k, n_{RS})^{H} or V₀(k,n)^{H} in the frequency domain, and the convolution operation unit performs a convolution operation between the time-domain signals, generated by the time-domain signal generation unit and the impulse responses of the product U₀(k, n_{RS})D0(k, n_{RS}) or U₀(k,n)D₀(k,n) read from the propagation path characteristic storage unit.

With this configuration, the test system according to the present invention can compress the data of V₀(k, n_{RS})^{H} or V₀(k,n)^{H} as information and store the data in the propagation path characteristic storage unit, by converting the V₀(k, n_{RS})^{H} or V₀(k,n)^{H} data in the frequency domain into an impulse response format.

Furthermore, the test system according to the present invention may be configured such that the singular value decomposition processing unit performs permutation of the singular values constituting the diagonal matrix D₀(k, n_{RS}) or D₀(k, n), permutation and phase adjustment of the column vectors constituting the sub-matrix U₀(k, n_{RS}) or U₀(k,n) of the unitary matrix, and permutation and phase adjustment of the column vectors constituting the sub-matrix V₀(k, n_{RS}) or V₀(k, n) of the unitary matrix, so that the elements of the product U₀(k, n_{RS})D₀(k, n_{RS}) or U₀(k,n)D₀(k,n), and the elements of the column vectors constituting the sub-matrix V₀(k, n_{RS}) or V₀(k, n) of the unitary matrix, continuously change between the adjacent instantaneous characteristics H(k, n_{RS}) or the interpolated propagation path characteristics H(k,n) in a frequency axis and a time axis.

With this configuration, the test system according to the present invention can assure continuity between adjacent instantaneous characteristics H(k, n_{RS}) or interpolated propagation path characteristics H(k,n) in the frequency axis and the time axis by performing, as necessary, permutation of the singular values constituting the diagonal matrix D₀(k, n_{RS}) or D₀(k, n), permutation and phase adjustment of the column vectors constituting the sub-matrix U₀(k, n_{RS}) or U₀(k, n) of the unitary matrix, and permutation and phase adjustment of the column vectors constituting the sub-matrix V₀(k,n) of the unitary matrix.

Furthermore, the test system according to the present invention may be configured such that the convolution operation unit performs the convolution operation by aligning the timing of the time-domain signal, including the test reference signal, with the timing of the impulse responses of the product U₀(k, n)D₀(k, n) at a timing n_{RS} where the test reference signal is included.

With this configuration, the test system according to the present invention can match the propagation path characteristics observed by the UE when referencing the test reference signal in a simulation environment with the propagation path characteristics observed by the antenna device through the reference signal in the actual propagation path environment, by performing the convolution operation by aligning a timing of the time-domain signals including the test reference signal with a timing of the impulse responses of the product U₀(k, n_{RS})D₀(k, n_{RS}) at a timing n_{RS} where the test reference signal is included.

In addition, according to the present invention, there is provided a test method for transmitting test signals to a device under test (120) having N_{Rx} receiving antennas, the test method including an actual propagation path characteristic calculation step (S2) of calculating instantaneous characteristics H(k, n_{RS}) of propagation path characteristics of an actual propagation path for each subcarrier fₖ and timing t_{nRS}, using reference signals included in IQ data of a downlink signal output from an antenna device (10) that receives the downlink signal transmitted from N_{Tx} transmitting antennas (Tx #1 to Tx #N_{Tx}) of a network-side transceiver (100) at N_{Rx} receiving antennas (Rx #1 to Rx #N_{Rx}) in an actual propagation path (110) environment, an interpolation processing step (S3) of interpolating the instantaneous characteristics H(k, n_{RS}) in a time axis direction to generate interpolated propagation path characteristics H(k,n) with a sampling rate that satisfies the sampling theorem, a singular value decomposition processing step (S4) of performing singular value decomposition on the interpolated propagation path characteristics H(k,n) into a form of H(k, n)=U₀(k, n)D₀(k, n)V₀(k, n)^{H}, and calculating an N_{Rx}-row R-column sub-matrix U₀ of a unitary matrix, an R-row R-column diagonal matrix D₀(k,n) whose diagonal components are the effective singular values of the interpolated propagation path characteristics H(k,n), and a conjugate-transpose matrix V₀(k, n)^{H} of an N_{Tx}-row R-column sub-matrix V₀(k,n) of a unitary matrix, where R is the number of effective singular values, steps (S5 to S7) of generating a test reference signal transmitted from the N_{Tx} transmitting antennas, a modulation signal of test data to be transmitted to the device under test, and N_{Tx} parallel test signals including the test reference signal in the frequency domain and the modulation signal in the frequency domain, a signal conversion step (S8) of converting the N_{Tx} parallel test signals into R parallel signals by multiplying the N_{Tx} parallel test signals by the conjugate-transpose matrix V₀(k,n)^{H}, a time-domain signal generation step (S9) of performing inverse Fourier transform processing on the R parallel signals to generate time-domain signals, and a convolution operation step (S10) of performing a convolution operation between the time-domain signals generated in the time-domain signal generation step and impulse responses of a product U₀(k, n)D₀(k, n) of the sub-matrix U₀(k, n) of the unitary matrix and the diagonal matrix D₀(k,n) to generate N_{Rx} parallel test signals in the time domain that are respectively received by the N_{Rx} receiving antennas of the device under test.

### Advantage of the Invention

According to the present invention, there is provided a test system and a test method capable of simulating a propagation path environment while suppressing the circuit scale, by using a method that reproduces the instantaneous characteristics of the propagation path characteristics of an actual propagation path.

### BRIEF DESCRIPTION OF THE DRAWINGS

FIG. 1 is a diagram schematically showing the environment of an actual propagation path between a base station (network-side transceiver) and an antenna device.

FIG. 2 is a block diagram showing the configuration of a test system according to an embodiment of the present invention.

FIG. 3 is a diagram illustrating the frequency domain of the propagation path characteristics and the characteristics thereof in the time domain showing the time variation of the propagation path characteristics.

FIG. 4 is a diagram showing a specific configuration of a test device and a pseudo-propagation path included in the test system according to the embodiment of the present invention.

FIG. 5 is a diagram showing a general configuration of a base station simulator and a propagation path simulator in the related art.

FIG. 6 is a schematic diagram for illustrating propagation path characteristics and digital beamforming between a base station and a UE.

FIG. 7 is a flowchart illustrating the processing of a test method using the test system according to the embodiment of the present invention.

### BEST MODE FOR CARRYING OUT THE INVENTION

Hereinafter, embodiments of a test system and a test method according to the present invention will be described with reference to the drawings.

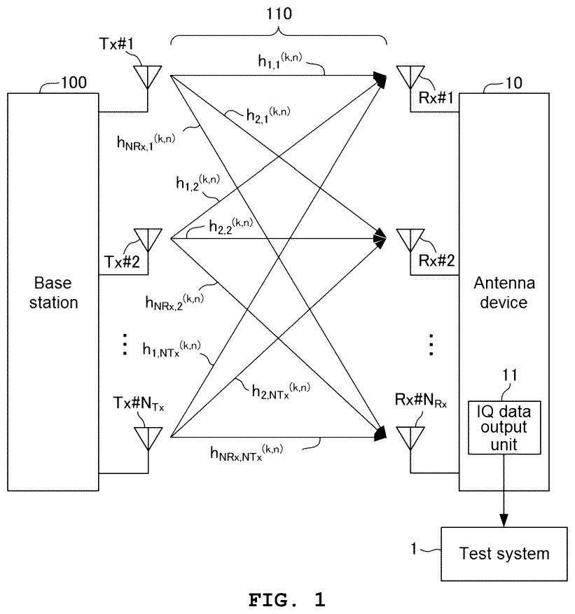

FIG. 1 is a diagram schematically showing the environment of an actual propagation path 110, which is a MIMO propagation path between a base station 100, an example of a network-side transceiver, and an antenna device 10. In FIG. 1, data communication between the base station 100 and the antenna device 10 is performed using a plurality of subcarriers based on the orthogonal frequency division multiplexing (OFDM) modulation scheme.

The antenna device 10 receives downlink signals transmitted from the N_{Tx} transmitting antennas Tx #1 to Tx #N_{Tx} of the base station 100 in an environment of the actual propagation path 110 configured with a plurality of channels. For example, the antenna device 10 is an air monitor or a UE, or the like. The antenna device 10 includes N_{Rx} receiving antennas Rx #1 to Rx #N_{Rx} that receive downlink signals transmitted from the transmitting antennas Tx #1 to Tx #N_{Tx} of the base station 100 as received signals, and an IQ data output unit 11.

Here, the number N_{Tx} of transmitting antennas Tx #1 to Tx #N_{Tx} of the base station 100 and the number N_{Rx} of receiving antennas Rx #1 to Rx #N_{Rx} of the antenna device 10 are integers of 2 or more and 1 or more, respectively, and the value of N_{Tx}×N_{Rx} becomes the number of channels of the actual propagation path 110.

The IQ data output unit 11 performs reception processing such as amplification, frequency conversion, and analog-to-digital conversion on the N_{Rx} received signals received by the receiving antennas Rx #1 to Rx #N_{Rx} of the antenna device 10. Furthermore, the IQ data output unit 11 demodulates the N_{Rx} received signals that have undergone reception processing to generate N_{Rx} sets of mutually orthogonal I-component baseband signals and Q-component baseband signals. In the present specification, the I-component baseband signals and Q-component baseband signals are collectively referred to simply as “IQ data.”

Reference signals (RS) included in the IQ data output from the IQ data output unit 11 of the antenna device 10 are, for example, a channel state information reference signal (CSI-RS), a demodulation reference signal (DMRS), a tracking reference signal (TRS), phase tracking reference signal (PTRS), or the like, in the case of the 5G NR standard.

In the present embodiment, the case of using a CSI-RS in a frequency range 1 (FR1) of the 5G NR standard as the above reference signal will be described as an example, but the reference signal is not limited to the CSI-RS and may be other RS mentioned above.

When the reference signal is a CSI-RS, situations where the number N-r of transmitting antennas Tx #1 to Tx #N_{Tx} is any of 4, 8, 12, 16, 24, or 32, and the number N_{Rx} of receiving antennas Rx #1 to Rx #N_{Rx} is any of 1, 2 or 4, are examples of situations where the present invention is applicable. In particular, when the number N_{Tx} of transmitting antennas Tx #1 to Tx #N_{Tx} is large compared to the number N_{Rx} of receiving antennas Rx #1 to Rx #N_{Rx}, the present invention is highly effective in suppressing the circuit scale of the test device.

h_{1,1}^{(k,n)}, h_{2,1}^{(k,n)}, . . . , h_{NRx,1}^{(k,n)}, h_{1,2}^{(k,n)}, h_{2,2}^{(k,n)}, h_{NRx,2}^{(k,n)}, . . . , h_{1,NTx}^{(k,n)}, h_{2,NTx}^{(k,n)}, . . . , h_{NRx,NTx}^{(k,n)} in FIG. 1 are elements of the N_{Tx}×N_{Rx} MIMO propagation path matrix in the frequency domain, as shown in Equation (3) described later.

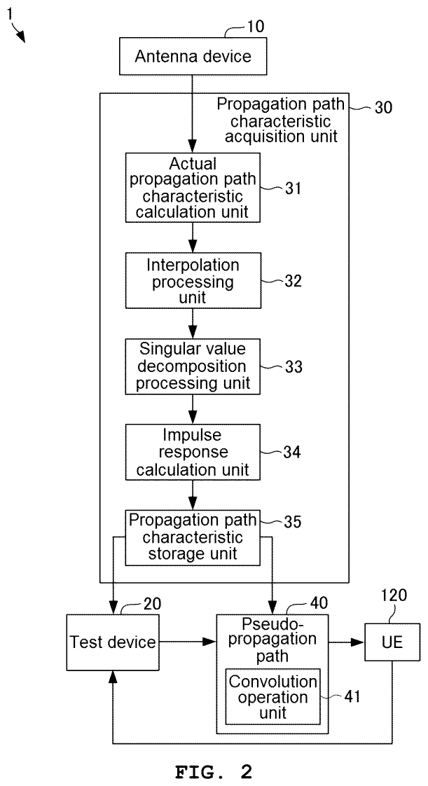

As shown in FIG. 2, a test system 1 of the present embodiment transmits test signals to a device under test (UE) 120 having N_{Rx} receiving antennas, and includes a test device 20, a propagation path characteristic acquisition unit 30, and a pseudo-propagation path 40.

The test device 20 has the function of a base station simulator that generates downlink signals necessary for testing the UE 120, transmits the generated downlink signals to the UE 120 via the pseudo-propagation path 40, receives uplink signals transmitted from the UE 120, and performs processing necessary for testing. The test device 20 is configured to perform a test of demodulation performance of the UE 120, for example. The pseudo-propagation path 40 between the test device 20 and the UE 120 is formed by an operation of a convolution operation unit 41 described below. The UE 120 is a UE capable of performing communication at least in a MIMO scheme or a multiple input single output (MISO) scheme.

The propagation path characteristic acquisition unit 30 includes an actual propagation path characteristic calculation unit 31, an interpolation processing unit 32, a singular value decomposition processing unit 33, an impulse response calculation unit 34, and a propagation path characteristic storage unit 35.

The actual propagation path characteristic calculation unit 31 performs fast Fourier transform (FFT) processing on N_{Rx} sets of IQ data output from the IQ data output unit 11 for each OFDM symbol, and by analyzing the CSI-RS, which is a known reference signal included in the IQ data in the frequency domain, calculates the instantaneous characteristics H(k, n_{RS}) of the propagation path characteristics in the frequency domain of a plurality of channels constituting the actual propagation path 110 for each subcarrier fₖ and timing t_{nRS}. That is, the actual propagation path characteristic calculation unit 31 can obtain the instantaneous characteristics H(k, n_{RS}) only at the timing when the CSI-RS is transmitted from the N_{Tx} transmitting antennas Tx #1 to Tx #N_{Tx} of the base station 100.

Here, the instantaneous characteristics H(k, n_{RS}) are shown as in the following Equation (1). h_{y,x}^{(k,n)} represents each element of the instantaneous characteristics H(k, n_{RS}). y is an index of the N_{Rx} receiving antennas Rx #1 to Rx #N_{Rx} of the antenna device 10, and is an integer from 1 to N_{Rx}. x is an index of the N_{Tx} transmitting antennas Tx #1 to Tx #N_{Tx} of the base station 100, and is an integer from 1 to N_{Tx}.

That is, N_{Rx}=1 and N_{Tx}≥2 represent a MISO scheme, and N_{Rx}≥2 and N_{Tx}≥2 represent a MIMO scheme.

$$\begin{matrix}[ Equation 1 ] & \\ H ( k , {n}_{RS} ) = [ {h}_{y , x}^{( k , {n}_{RS} )} ] = [ \begin{matrix}{h}_{1 , 1}^{( k , {n}_{RS} )} & {h}_{1 , 2}^{( k , {n}_{RS} )} & … & {h}_{1 , {N}_{Tx}}^{( k , {n}_{RS} )} \\ {h}_{2 , 1}^{( k , {n}_{RS} )} & {h}_{2 , 2}^{( k , {n}_{RS} )} & … & {h}_{2 , {N}_{Tx}}^{( k , {n}_{RS} )} \\ ⋮ & ⋮ & ⋱ & ⋮ \\ {h}_{{N}_{Rx} , 1}^{( k , {n}_{RS} )} & {h}_{{N}_{Rx} , 2}^{( k , {n}_{RS} )} & … & {h}_{{N}_{Rx} , {N}_{Tx}}^{( k , {n}_{RS} )}\end{matrix} ] & ( 1 )\end{matrix}$$

In Equation (1), k is a sample number on the frequency axis, for example, an index of a subcarrier number. Also, n_{RS} is a sample number on the time axis corresponding to the timing of the CSI-RS in the downlink signal transmitted from the base station 100, for example, an index of an OFDM symbol number. Furthermore, the average power of the propagation path characteristic h_{y,x}^{(k,n)} is assumed to be normalized to 1.

Each element h_{y,x}^{(k,nRS)} of the instantaneous characteristics H(k, n_{RS}) includes information on the amplitude variation amount and phase variation amount of the CSI-RS in the IQ data obtained from the received signal received by the y-th receiving antenna Rx #y for the known CSI-RS transmitted by the x-th transmitting antenna Tx #x.

The pseudo-propagation path 40 functions as a propagation path simulator formed between the test device 20 and the UE 120. The pseudo-propagation path 40 is configured to reproduce propagation path characteristics interpolated as necessary by the interpolation processing unit 32, described later (hereinafter, also referred to as interpolated propagation path characteristics H(k,n)).

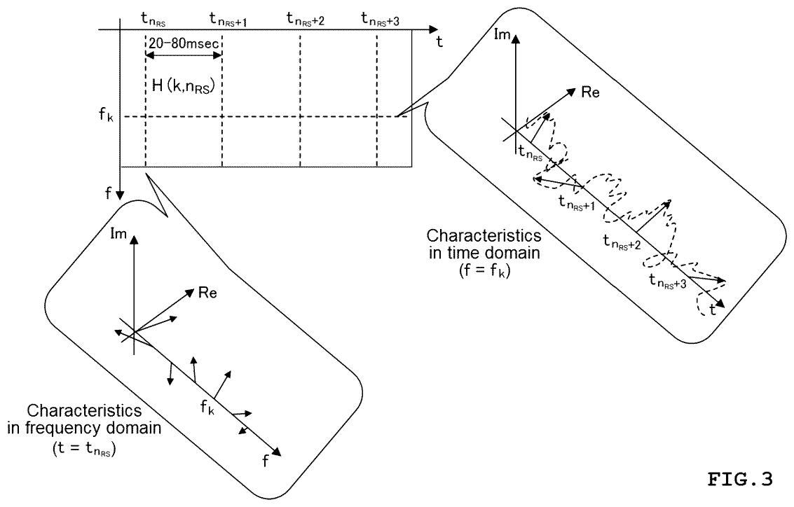

As shown in FIG. 3, for certain instantaneous characteristics H(k, n_{RS}), a series of data obtained by varying n_{RS} (timing t_{nRS}) along a time axis t direction at a certain k (a certain frequency fₖ) on a frequency axis f represents time-domain instantaneous characteristics indicating the change in instantaneous values along the time axis of the instantaneous characteristics H(k, n_{RS}). On the right side of FIG. 3 is a vector-expression graph of the real and imaginary parts of the time-domain instantaneous characteristics of the instantaneous characteristics H(k, n_{RS}). On the lower side of FIG. 3 is a vector-expression graph of the real and imaginary parts of the characteristics of the instantaneous characteristics H(k, n_{RS}) in the frequency domain.

The propagation path characteristics in the actual propagation path 110 can be directly measured only every period T (for example, T=20 msec to 80 msec) when reference signals such as CSI-RS are transmitted. The relationship between the maximum Doppler frequency f_{d} of the actual propagation path 110 and the period T is often in a situation as shown in the following Equation (2), but such a situation does not satisfy the Nyquist criterion in the sampling theorem.

$$\begin{matrix}[ Equation 2 ] & \\ T \geq \frac{1}{2 {f}_{d}} & ( 2 )\end{matrix}$$

For example, to satisfy the Nyquist criterion at T=80 msec, it is necessary that f_{d}<6.25 Hz, which is limited to cases where the movement speed v of the UE 120 is v<1.35 km/h when the carrier frequency is 5 GHz.

Meanwhile, the data of the time-domain instantaneous characteristics of the interpolated propagation path characteristics H(k,n) reproduced by the pseudo-propagation path 40 (hereinafter, also referred to as “instantaneous propagation path waveform data”) must be waveform data sampled at a sufficiently high sampling rate (for example, 10 kHz) to satisfy the sampling theorem.

Therefore, when the sample interval (interval of n_{RS}) of the instantaneous characteristics H(k, n_{RS}) does not satisfy the sampling theorem, the interpolation processing unit 32 interpolates the instantaneous characteristics H(k, n_{RS}) in the time axis direction to generate time-series data of interpolated propagation path characteristics H(k,n) at a sampling rate that satisfies the Nyquist criterion in the sampling theorem, as shown in the following Equation (3). This time-series data is instantaneous propagation path waveform data, where n is the sample number on the time axis.

In the present specification, when the sample interval of the instantaneous characteristics H(k, n_{RS}) satisfies the sampling theorem, the instantaneous characteristics H(k, n_{RS}) themselves are the interpolated propagation path characteristics H(k,n), and the interpolation processing unit 32 outputs the instantaneous characteristics H(k, n_{RS}) as is, as the interpolated propagation path characteristics H(k,n).

$$\begin{matrix}[ Equation 3 ] & \\ H ( k , n ) = [ \begin{matrix}{h}_{1 , 1}^{( k , n )} & {h}_{1 , 2}^{( k , n )} & … & {h}_{1 , {N}_{Tx}}^{( k , n )} \\ {h}_{2 , 1}^{( k , n )} & {h}_{2 , 2}^{( k , n )} & … & {h}_{2 , {N}_{Tx}}^{( k , n )} \\ ⋮ & ⋮ & ⋱ & ⋮ \\ {h}_{{N}_{Rx} , 1}^{( k , n )} & {h}_{{N}_{Rx} , 2}^{( k , n )} & … & {h}_{{N}_{Rx} , {N}_{Tx}}^{( k , n )}\end{matrix} ] & ( 3 )\end{matrix}$$

The interpolation processing by the interpolation processing unit 32 can be realized, for example, by a method utilizing the known Kalman filter. This method is disclosed, for instance, in “Interpolation of Sparely-Sampled Time-Variant Channel Response in 1D Trajectory Utilizing Ensemble Kalman Filter” by Nopphon Keerativoranan and Junichi Takada, 2022 IEEE 33rd Annual International Symposium on Personal, Indoor and Mobile Radio Communications.

The singular value decomposition processing unit 33 performs singular value decomposition on the interpolated propagation path characteristics H(k,n) that are processed by the interpolation processing unit 32, as shown in the following Equation (4). In Equation (4), U(k,n) is a unitary matrix of N_{Rx} rows and N_{Rx} columns, and V(k,n) is a unitary matrix of N_{Tx} rows and N_{Tx} columns. D(k,n) is a matrix of N_{Rx} rows and N_{Tx} columns, which is composed of elements of a diagonal matrix of N_{Rx} rows and N_{Rx} columns, and elements of a zero matrix of N_{Rx} rows and (N_{Tx}-N_{Rx}) columns, arranged in parallel. “A^{H}” represents the conjugate transpose (Hermitian transpose) of matrix A.

D₀(k,n) is an R-row R-column diagonal matrix whose diagonal components are R effective singular values λ_{i,i}(k,n) (singular values of non-negligible magnitude) included in D(k,n). Here, i is an integer from 1 to R. U₀(k,n) is an N_{Rx}-row R-column sub-matrix of a unitary matrix, composed of the column vectors corresponding to the R singular values λ_{i,i}(k,n) among the column vectors constituting U(k, n). V₀(k, n) is an N_{Tx}-row R-column sub-matrix of a unitary matrix, composed of the column vectors corresponding to the R singular values λ_{i,i}(k,n) among the column vectors constituting V(k,n).

When the sample interval of the instantaneous characteristics H(k, n_{RS}) satisfies the sampling theorem, the notation of the sample number n in U(k,n), U₀(k,n), V(k,n), V₀(k,n), D(k,n), D₀(k,n), λ_{i,i}(k,n), and various other parameters can be replaced with the sample number n_{RS}.

$$\begin{matrix}[ Equation 4 ] & \\ H ( k , n ) = U ( k , n ) D ( k , n ) {V ( k , n )}^{H} \approx {U}_{0} ( k , n ) {D}_{0} ( k , n ) {{V}_{0} ( k , n )}^{H} & ( 4 )\end{matrix}$$

$$Here , U ( k , n ) = [ \begin{matrix}{u}_{1} & {u}_{2} & … & {u}_{R} & … & {u}_{{N}_{Rx}}\end{matrix} ] , {U}_{0} ( k , n ) = [ \begin{matrix}{u}_{1} & {u}_{2} & … & {u}_{R}\end{matrix} ]$$

$${u}_{i} : Column vectors having {N}_{Rx} elements$$

$$V ( k , n ) = [ \begin{matrix}{v}_{1} & {v}_{2} & … & {v}_{R} & … & {v}_{{N}_{Tx}}\end{matrix} ] , {V}_{0} ( k , n ) = [ \begin{matrix}{v}_{1} & {v}_{2} & … & {v}_{R}\end{matrix} ]$$

$${v}_{i} : Column vectors having {N}_{Tx} elements$$

$$D ( k , n ) = [ \begin{matrix}{λ}_{1 , 1}^{( k , n )} & 0 & … & 0 & 0 & … & 0 \\ 0 & {λ}_{2 , 2}^{( k , n )} & … & 0 & 0 & … & 0 \\ ⋮ & ⋮ & ⋱ & ⋮ & ⋮ & … & ⋮ \\ 0 & 0 & … & {λ}_{{N}_{Rx} , {N}_{Tx}}^{( k , n )} & 0 & … & 0\end{matrix} ]$$

$${D}_{0} ( k , n ) = [ \begin{matrix}{λ}_{1 , 1}^{( k , n )} & 0 & … & 0 \\ 0 & {λ}_{2 , 2}^{( k , n )} & … & 0 \\ ⋮ & ⋮ & ⋱ & ⋮ \\ 0 & 0 & … & {λ}_{R , R}^{( k , n )}\end{matrix} ]$$

That is, the singular value decomposition processing unit 33 calculates an N_{Rx}-row R-column sub-matrix U₀(k, n) of a unitary matrix, an R-row R-column diagonal matrix D₀(k,n) whose diagonal components are the effective singular values of the interpolated propagation path characteristics H(k,n), and a conjugate-transpose matrix V₀(k,n)^{H} of an N_{Tx}-row R-column sub-matrix V₀ of a unitary matrix, by performing singular value decomposition on the interpolated propagation path characteristics H(k,n) into the form H(k, n)=U₀(k, n)D₀(k, n) V₀(k, n)^{H}, where R is the number of effective singular values, as shown in Equation (4).

Equation (4) can also be described as in the following Equation (5).

$$\begin{matrix}[ Equation 5 ] & \\ H ( k , n ) = {U}_{0} ( k , n ) {D}_{0} ( k , n ) {{V}_{0} ( k , n )}^{H} = [ \begin{matrix}{u}_{1} & {u}_{2} & … & {u}_{R}\end{matrix} ] [ \begin{matrix}{λ}_{1 , 1}^{( k , n )} & 0 & … & 0 \\ 0 & {λ}_{2 , 2}^{( k , n )} & … & 0 \\ ⋮ & ⋮ & ⋱ & ⋮ \\ 0 & 0 & … & {λ}_{R , R}^{( k , n )}\end{matrix} ] [ \begin{matrix}{v}_{1} & {v}_{2} & … & {v}_{R}\end{matrix} ] = {λ}_{1 , 1}^{( k , n )} {u}_{1} {v}_{1}^{H} + {λ}_{2 , 2}^{( k , n )} {u}_{2} {v}_{2}^{H} + … + {λ}_{R , R}^{( k , n )} {u}_{R} {v}_{R}^{H} & ( 5 )\end{matrix}$$

As shown in Equation (5), the singular value decomposition on the interpolated propagation path characteristics H(k,n) can be expressed as a sum over i=1 to R of the product of λ_{i,i}(k,n), the column vector u (bold) ᵢ constituting U₀(k,n), and the conjugate transpose v (bold) ᵢ^{H} of the column vector constituting V₀(k,n). In this sum, each term λ_{i,i}^{(k,n)}u (bold) ᵢv (bold) ᵢ^{H} is equivalent, and there is no basis for determining the order therebetween, so the result does not change even when the order of the column vectors corresponding to the singular values is interchanged when expressed in matrix form. For example, even when the first and second column vectors and corresponding singular values are interchanged and written as in the following Equation (6), the calculation result is equivalent.

$$\begin{matrix}[ Equation 6 ] & \\ H ( k , n ) = {U}_{0} ( k , n ) {D}_{0} ( k , n ) {{V}_{0} ( k , n )}^{H} = [ \begin{matrix}{u}_{1} & {u}_{2} & … & {u}_{R}\end{matrix} ] [ \begin{matrix}{λ}_{2 , 2}^{( k , n )} & 0 & … & 0 \\ 0 & {λ}_{1 , 1}^{( k , n )} & … & 0 \\ ⋮ & ⋮ & ⋱ & ⋮ \\ 0 & 0 & … & {λ}_{R , R}^{( k , n )}\end{matrix} ] [ \begin{matrix}{v}_{1} & {v}_{2} & … & {v}_{R}\end{matrix} ] & ( 6 )\end{matrix}$$

As a convention when displaying the results of singular value decomposition, the singular values, which are the diagonal components of the diagonal matrix D₀(k,n), are usually arranged in descending order such that λ_{1,1}^{(k,n)}≥λ_{2,2}^{(k,n)}≥ . . . ≥λ_{R,R}^{(k,n)}. When samples of U₀(k, n)D₀(k, n) and V₀(k,n)^{H} are arranged on the frequency axis and time axis according to this conventional column vector order, it is considered that continuity regarding the order of column vectors may or may not be assured.

That is, when there is a clear difference in the magnitude of each of the R singular values λ_{1,1}^{(k,n)}, λ_{2,2}^{(k,n)}, . . . , λ_{R,R}^{(k,n)} and the correlation therebetween does not change on the frequency axis and time axis, then continuity regarding the order of column vectors is assured. On the other hand, when values of approximately the same magnitude are included among the R singular values λ_{1,1}^{(k,n)}, λ_{2,2}^{(k,n)}, . . . , λ_{R,R}^{(k,n)} and the magnitudes thereof are reversed in the frequency axis or time axis direction, then continuity regarding the order of column vectors is not assured.

Furthermore, regarding the relative phase relationship of U₀(k,n)D₀(k,n) and V₀(k,n)^{H}, there is a degree of freedom as shown in the following Equation (7), which may be a factor preventing the continuity of phase in the frequency axis or time axis direction from being assured.

$$\begin{matrix}[ Equation 7 ] & \\ H ( k , n ) = {U}_{0} ( k , n ) {D}_{0} ( k , n ) {{V}_{0} ( k , n )}^{H} = \{ {U}_{0} ( k , n ) {D}_{0} ( k , n ) Θ ( k , n ) \} {\{ {V}_{0} ( k , n ) Θ ( k , n ) \}}^{H} & ( 7 )\end{matrix}$$

$$Here , θ ( k , n ) = [ \begin{matrix}{e}^{j {θ}_{1 , 1}^{( k , n )}} & 0 & … & 0 \\ 0 & {e}^{j {θ}_{2 , 2}^{( k , n )}} & … & 0 \\ ⋮ & ⋮ & ⋱ & ⋮ \\ 0 & 0 & … & {e}^{j {θ}_{R , R}^{( k , n )}}\end{matrix} ]$$

Therefore, to exclude the “possibility that continuity regarding column vector permutation is not assured” and “possibility that phase continuity is not assured” described above, processing is required to assure continuity when samples of U₀(k, n)D₀(k, n) and V₀(k, n)^{H} are arranged on the frequency axis and time axis. Such mathematical processing is well-known, and an example of such processing is described in “Untangling the SVD's of Random Matrix Sample Paths”, by David W. Browne, Michael W. Browne, Michael P. Fitz, arXiv:math/0610088v1 [math.ST]2 Oct. 2006.

Therefore, the singular value decomposition processing unit 33 is configured to perform permutation of the singular values λ_{i,i}^{(k,n)} constituting the diagonal matrix D₀(k,n), permutation and phase adjustment of the column vectors u (bold) i constituting the sub-matrix U₀(k,n) of the unitary matrix, and permutation and phase adjustment of the column vectors v (bold) i constituting the sub-matrix V₀(k,n) of the unitary matrix, so that the elements of the product U₀(k,n)D₀(k,n) of the sub-matrix U₀(k,n) of the unitary matrix and the diagonal matrix D₀(k,n), and the elements of the column vectors v (bold) i constituting the sub-matrix V₀(k,n) of the unitary matrix, change continuously between adjacent interpolated propagation path characteristics H(k,n) on the frequency axis and time axis.

The propagation path characteristic storage unit 35 is configured to store the impulse responses of V₀(k,n)^{H} and the impulse responses of the product U₀(k, n)D₀(k, n), which are calculated by an impulse response calculation unit 34 described later.

The impulse response calculation unit 34 is configured to convert the frequency characteristics of U₀(k, n)D₀(k, n) and V₀(k,n)^{H} along the frequency axis direction, for which singular value decomposition and continuity assurance are performed by the singular value decomposition processing unit 33, into time-varying impulse responses (corresponding to each sample number n), using, for example, inverse digital Fourier transformation (IDFT) which converts frequency characteristics to impulse responses.

The impulse response calculation unit 34 can calculate impulse responses from the frequency characteristics of U₀(k,n)D₀(k,n) and V₀(k,n)^{H} using the following Equations (8a) to (8e), which represent IDFT in matrix form.

$$\begin{matrix}[ Equation 8 ] & \\ [ \begin{matrix}{h}_{freq} ( 1 , n ) \\ {h}_{freq} ( 2 , n ) \\ ⋮ \\ {h}_{freq} ( K , n )\end{matrix} ] = W [ \begin{matrix}g ( 1 , n ) \\ g ( 2 , n ) \\ ⋮ \\ g ( L , n )\end{matrix} ] & ( 8 a )\end{matrix}$$

$$Here , [ \begin{matrix}{h}_{freq} ( 1 , n ) \\ {h}_{freq} ( 2 , n ) \\ ⋮ \\ {h}_{freq} ( K , n )\end{matrix} ] \begin{matrix}are frequency \\ characteristics \\ and\end{matrix} , [ \begin{matrix}g ( 1 , n ) \\ g ( 2 , n ) \\ ⋮ \\ g ( L , n )\end{matrix} ] \begin{matrix}are impulse \\ responses\end{matrix} . \\ W = [ \begin{matrix}{w}_{1} & {w}_{2} & … & {w}_{L}\end{matrix} ] \qquad ( 8 b )$$

$${w}_{i} = [ \begin{matrix}{e}^{- j 2 {πτ}_{i} {f}_{1}} \\ {e}^{- j 2 {πτ}_{i} {f}_{2}} \\ ⋮ \\ {e}^{- j 2 {πτ}_{i} {f}_{K}}\end{matrix} ] \qquad ( 8 c )$$

$${τ}_{i} = ( l - 1 ) \cdot Δ T \qquad ( 8 d )$$

$${f}_{K} = {f}_{0} + ( k + 1 ) \cdot Δ F \qquad ( 8 e )$$

When the frequency characteristics in Equation (8a) are known, the impulse response can be calculated as in the following Equation (9) using a generalized inverse matrix W⁺ of a DFT matrix W.

$$\begin{matrix}[ Equation 9 ] & \\ [ \begin{matrix}g ( 1 , n ) \\ g ( 2 , n ) \\ ⋮ \\ g ( L , n )\end{matrix} ] = {W}^{+} [ \begin{matrix}{h}_{freq} ( 1 , n ) \\ {h}_{freq} ( 2 , n ) \\ ⋮ \\ {h}_{freq} ( K , n )\end{matrix} ] & ( 9 )\end{matrix}$$

Alternatively, the impulse response calculation unit 34 may calculate impulse responses that accurately reproduce the respective frequency characteristics of U₀(k, n)D₀(k, n) and V₀(k,n)^{H} even when there is a limit to the number of taps of the impulse responses, for example, by utilizing the space-alternating generalized expectation-maximization (SAGE) algorithm. The processing of the SAGE algorithm is described, for example, in “Channel Parameter Estimation in Mobile Radio Environments Using the SAGE Algorithm” by Bernard H. Fleury, Martin Tschudin, Ralf Heddergott, Dirk Dahlhaus, and Klaus Ingeman Pedersen, IEEE JOURNAL ON SELECTED AREAS IN COMMUNICATIONS, VOL. 17, NO. 3, MARCH 1999.

Although V₀(k,n)^{H} does not inherently need to be converted to impulse responses because V₀(k,n)^{H} is multiplied by data as frequency characteristics in a signal conversion unit 24 described later, the impulse response calculation unit 34 converts V₀(k,n)^{H} to impulse responses to compress the size of the instantaneous propagation path waveform data stored in the propagation path characteristic storage unit 35.

For example, in the 5G NR standard, when V₀(k,n)^{H} is stored under the conditions below, holding V₀(k,n)^{H} as impulse responses can compress the data amount more than storing V₀(k,n)^{H} as frequency characteristics.

For example, when V₀(k,n)^{H} is stored as frequency characteristics in the propagation path characteristic storage unit 35, where the sample interval in the frequency axis direction is 1 resource block (RB) width (12 subcarriers), the signal bandwidth is 273 RB, and the bit count for the real and imaginary parts is 2 Bytes for the real part+2 Bytes for the imaginary part, then the data amount calculated for one OFDM symbol per channel is 273×(2 Bytes+2 Bytes)=1092 Bytes.

On the other hand, when V₀(k,n)^{H} is stored as impulse responses in the propagation path characteristic storage unit 35, where the number of delay taps is 24 taps and the bit count for the real and imaginary parts is 2 Bytes for the real part+2 Bytes for the imaginary part, then the data amount calculated for one OFDM symbol per channel is 24×(2 Bytes+2 Bytes)=96 Bytes.

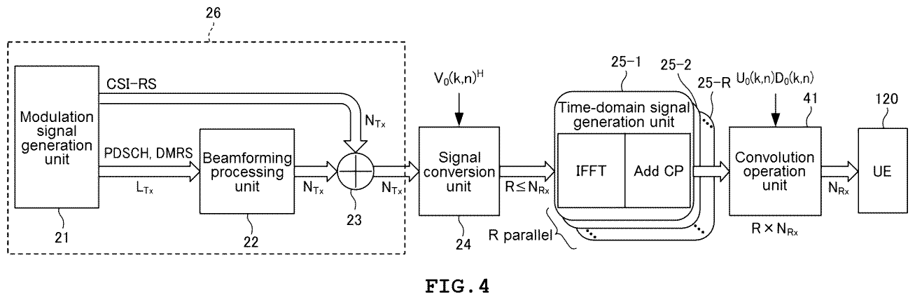

FIG. 4 is a diagram showing a more specific configuration of the test device 20 and the pseudo-propagation path 40 in the present embodiment.

The test device 20 includes a modulation signal generation unit 21, a beamforming processing unit 22, an integration unit 23, the signal conversion unit 24, and a time-domain signal generation unit 25. The modulation signal generation unit 21, the beamforming processing unit 22, and the integration unit 23 constitute a test signal generation unit 26. The pseudo-propagation path 40 includes a convolution operation unit 41.

The test signal generation unit 26 is configured to generate a test reference signal of the same format as reference signals transmitted from the N_{Tx} transmitting antennas Tx #1 to Tx #N_{Tx}, a modulation signal of test data to be transmitted to the UE 120, and N_{Tx} parallel test signals including a test reference signal in the frequency domain and a modulation signal in the frequency domain.

The modulation signal generation unit 21 converts (generates) test data for L_{TX} layers to be transmitted to the UE 120 into L_{TX} parallel modulation signals in the frequency domain, and also generates a CSI-RS in the frequency domain as a test reference signal. The L_{Tx} parallel modulation signals simulate signals transmitted via a physical downlink shared channel (PDSCH), which is a data channel. DMRS is a reference signal associated with the PDSCH.

The modulation signal generated by the modulation signal generation unit 21 is, for example, a modulation signal modulated by a multi-level modulation scheme such as binary phase shift keying (BPSK), quadrature phase shift keying (QPSK), 16QAM (Quadrature Amplitude Modulation), 64QAM, or 256QAM.

The beamforming processing unit 22 performs digital arithmetic processing equivalent to digital beamforming processing for achieving desired beam characteristics of radio waves of the L_{Tx} parallel downlink signals transmitted from the N_{Tx} transmitting antennas Tx #1 to Tx #N_{Tx}, on the modulation signal in the frequency domain, generated by the modulation signal generation unit 21, to generate N_{Tx} parallel beamforming processed signals.

The integration unit 23 adds a CSI-RS as a test reference signal in the frequency domain to each of the N_{Tx} parallel beamforming processed signals, thereby generating N_{Tx} parallel test signals in the frequency domain. The integration unit 23 can be configured, for example, with an adder.

When the CSI-RS and the N_{Tx} parallel beamforming processed signals are not simultaneously allocated on radio resources (radio resources expressed by two axes: frequency axis and time axis) in the test signal, the integration unit 23 will simply output either the N_{Tx} parallel beamforming processed signals or the CSI-RS. Therefore, the integration unit 23 may be configured with a selector that selects and outputs either the N_{Tx} parallel beamforming processed signals or the CSI-RS.

The signal conversion unit 24 converts the N_{Tx} parallel test signals into R parallel signals by performing a conversion to return the impulse responses of V₀(k,n)^{H} read from the propagation path characteristic storage unit 35 back to V₀(k,n)^{H} in the frequency domain, and then multiplying the N_{Tx} parallel test signals by V₀(k,n)^{H} in the frequency domain. For example, the signal conversion unit 24 performs processing to calculate V₀(k,n)^{H} in the frequency domain from the impulse responses of V₀(k,n)^{H} using Equation (8a).

The time-domain signal generation units 25 (25-1, 25-2, . . . , 25-R) perform inverse fast Fourier transform (IFFT) processing, cyclic prefix (CP) addition processing, band limitation processing, or the like, on the R parallel test signals in the frequency domain converted by the signal conversion unit 24, thereby generating OFDM-modulation signals in the time domain (hereinafter, also referred to as “OFDM modulation signals”).

The test signals in the frequency domain output from the integration unit 23, corresponding to each transmitting antenna Tx #1 to Tx #N_{Tx}, are data in which constellations are arranged subcarrier by subcarrier (index k) along the frequency axis direction.

Here, when the constellation data transmitted by the j-th transmitting antenna (j is an integer from 1 to N_{Tx}) on the subcarrier #k in the OFDM symbol #n is denoted as sⱼ^{(k,n)}, then the test signals output from the integration unit 23 become data in the form of column vectors, as shown in the following Equation (10), arranged in parallel along the frequency axis (index k) and time axis (index n).

$$\begin{matrix}[ Equation 10 ] & \\ [ \begin{matrix}{s}_{1}^{( k , n )} \\ {s}_{2}^{( k , n )} \\ ⋮ \\ {s}_{{N}_{Tx}}^{( k , n )}\end{matrix} ] & ( 10 )\end{matrix}$$

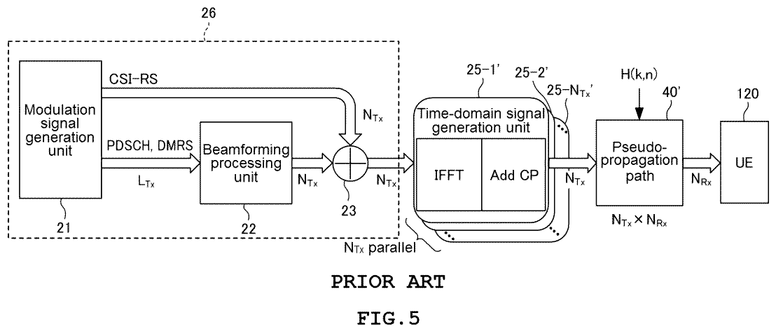

FIG. 5 is a diagram showing the general processing form of a base station simulator and a propagation path simulator in the related art. In a general processing form, data sⱼ^{(k,n)} for the j-th transmitting antenna Tx #j within the elements of the column vector of Equation (10) is input to the j-th time-domain signal generation unit 25-j′ to generate an OFDM modulation signal, and signals corresponding to each transmitting antenna Tx #1 to Tx #N_{Tx} are input to a pseudo-propagation path 40′ of MIMO channel size N_{Tx}×NRx.

Meanwhile, in the processing form of the present embodiment shown in FIG. 4, by multiplying the column vector of Equation (10) by V₀(k,n)^{H}, the number of elements is reduced from N_{Tx} to R, as shown in the following Equation (11).

$$\begin{matrix}[ Equation 11 ] & \\ [ \begin{matrix}{sm}_{1}^{( k , n )} \\ {sm}_{2}^{( k , n )} \\ ⋮ \\ {sm}_{{N}_{Tx}}^{( k , n )}\end{matrix} ] {[ \begin{matrix}{v}_{1} & {v}_{2} & … & {v}_{R}\end{matrix} ]}^{H} [ \begin{matrix}{s}_{1}^{( k , n )} \\ {s}_{2}^{( k , n )} \\ ⋮ \\ {s}_{{N}_{Tx}}^{( k , n )}\end{matrix} ] & ( 11 )\end{matrix}$$

The j-th data smⱼ^{(k,n)} (j is an integer from 1 to R) in the column vector with R elements on the left side of Equation (11) is input to the j-th time-domain signal generation unit 25-j to generate an OFDM modulation signal, and each of the R OFDM modulation signals is input to the pseudo-propagation path 40 of MIMO channel size R×N_{Rx}.

That is, the signal conversion unit 24 in the present embodiment can reduce the number of paths from the processing of the time-domain signal generation unit 25 onward from the number of transmitting antennas N_{Tx} to R, which is the number of effective singular values. R is a value equal to or smaller than the smaller value of N_{Tx} and N_{Rx} (R≤Min(N_{Tx}, N_{Rx})). For example, when the number of transmitting antennas N_{Tx} is 32 and the number of receiving antennas N_{Rx} is 4, R can be set to a value of 4 or less. This makes it possible to reduce the hardware resources required from the time-domain signal generation unit 25 onward.

The convolution operation unit 41 performs a convolution operation in the time domain between the OFDM modulation signal generated by the time-domain signal generation unit 25 and the impulse responses of the product U₀(k,n)D₀(k,n) read from the propagation path characteristic storage unit 35, thereby generating N_{Rx} parallel test signals in the time domain that are respectively received by the N_{Rx} receiving antennas of the UE 120.

That is, the convolution operation unit 41 in the present embodiment can reduce the MIMO channel size of the pseudo-propagation path 40 applied in the time domain from N_{Tx}×N_{Rx} to R×N_{Rx}. However, for example, when N_{Tx}>N_{Rx}, since R fluctuates sequentially within the range of R≤N_{Rx}, it is necessary to prepare N_{Rx} paths instead of R paths in the pseudo-propagation path 40.

In the present embodiment, the timing relationship between the OFDM modulation signal generated by the time-domain signal generation unit 25 and the interpolated propagation path characteristics H(k,n) reproduced by the pseudo-propagation path 40 when testing the UE 120 with the test device 20 and the pseudo-propagation path 40 is as follows.

That is, the test system 1 of the present embodiment is configured to align the timing when the modulation signal generation unit 21 generates a CSI-RS and the CSI-RS is processed by the pseudo-propagation path 40 with the timing when the instantaneous characteristics H(k, n_{RS}) based on the direct measurement of the CSI-RS by the antenna device 10 are reproduced in the pseudo-propagation path 40.

This can be achieved, for example, when the convolution operation unit 41 aligns the impulse response timing of an OFDM modulation signal (which includes a CSI-RS as a test reference signal) with the impulse response timing of the product U₀(k,n)D₀(k,n) at the timing n_{RS} (also including a CSI-RS as a test reference signal), and then performs a convolution operation on the OFDM modulation signal that includes the same CSI-RS.

As a result, the propagation path characteristics observed by the UE 120 when referencing a CSI-RS in a simulation environment can be matched with the propagation path characteristics observed by the antenna device 10 through the same CSI-RS in the actual propagation path 110 environment. That is, the propagation path characteristics observed by the UE 120 do not need to be affected by errors in the interpolation processing of the instantaneous characteristics H(k, n_{RS}) by the interpolation processing unit 32.

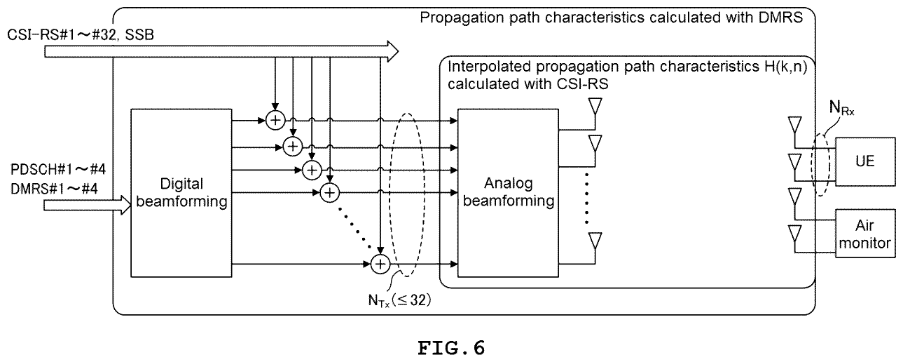

FIG. 6 is a schematic diagram for describing the propagation path characteristics between a 5G NR base station and a UE, and digital beamforming used in FR1.

For example, when DMRS of PDSCH is used as a reference signal, by analyzing DMRS, propagation path characteristics including digital beamforming characteristics or precoding characteristics (“propagation path characteristics calculated with DMRS” in FIG. 6) will be simulated. In such a method, propagation path characteristics can only be measured for a specific frequency band and time period for the data signal.

In contrast, what the test system 1 of the present embodiment simulates is the “interpolated propagation path characteristics H(k,n) calculated by the CSI-RS” in FIG. 6. Since the CSI-RS is a reference signal transmitted from the base station over a wide frequency band at constant time intervals, the test system 1 of the present embodiment can measure and reproduce instantaneous propagation path characteristics over a wide frequency band at constant time intervals by analyzing the CSI-RS.

In FIG. 6, the number of physical antennas after analog beamforming processing is equal to or greater than the number of transmitting antenna ports N_{Tx} after digital beamforming processing. In practice, if the number of antennas after analog beamforming processing is equal to or greater than the number of transmitting antennas N_{Tx}, it does not affect the maximum number of transmission layers (Rank) of the instantaneous characteristics H(k, n_{RS}) obtained. In the present specification, the transmitting antenna port of the RS to be analyzed is referred to as a “transmitting antenna”, and when, for example, analog beamforming follows, the propagation path characteristics analyzed with the RS to be analyzed are considered to include those characteristics.

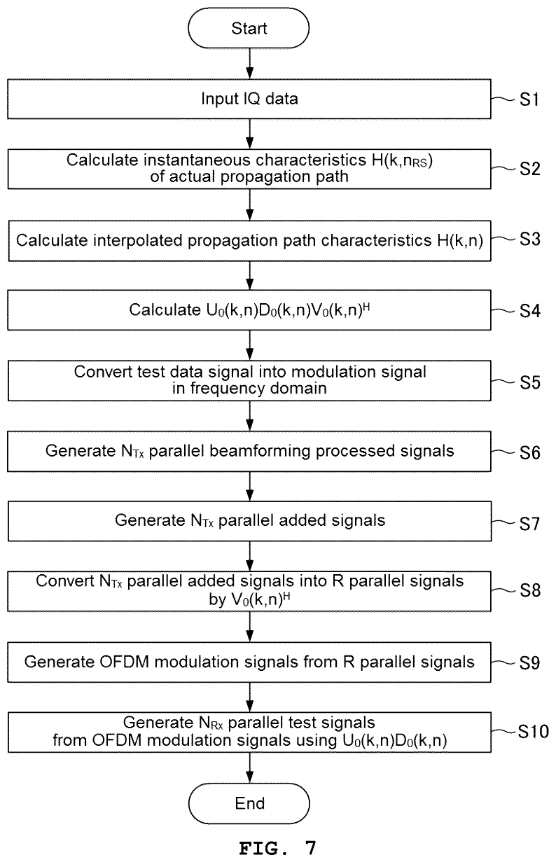

Hereinafter, an example of the processing of a test method using the test system 1 of the present embodiment will be described with reference to the flowchart in FIG. 7. Descriptions overlapping with the description of the configuration of the test system 1 above will be omitted as appropriate.

First, IQ data of a downlink signal from the base station 100 is input from the IQ data output unit 11 of the antenna device 10 to the propagation path characteristic acquisition unit 30 (step S1).

Next, the actual propagation path characteristic calculation unit 31 calculates the instantaneous characteristics H(k, n_{RS}) of the propagation path characteristics of the actual propagation path 110 for each subcarrier fₖ and timing t_{nRS}, using the CSI-RS included in the IQ data input in step S1 (actual propagation path characteristic calculation step S2).

Next, the interpolation processing unit 32 interpolates the instantaneous characteristics H(k, n_{RS}) in the time axis direction to generate interpolated propagation path characteristics H(k,n) with a sampling rate that satisfies the sampling theorem (interpolation processing step S3). However, interpolation processing is necessary only when the sample interval (interval of n_{RS}) of the instantaneous characteristics H(k,nRS) does not satisfy the sampling theorem. When the sample interval of the instantaneous characteristics H(k, n_{RS}) satisfies the sampling theorem, the instantaneous characteristics H(k, n_{RS}) themselves become the interpolated propagation path characteristics H(k,n).

Next, the singular value decomposition processing unit 33 performs singular value decomposition on the interpolated propagation path characteristics H(k,n) into the form H(k, n)=U₀(k, n)D₀(k, n) V₀(k, n)^{H}, and calculates an N_{Rx}-row R-column sub-matrix U₀ of a unitary matrix, an R-row R-column diagonal matrix D₀(k,n) whose diagonal components are the effective singular values of the interpolated propagation path characteristics H(k,n), and a conjugate-transpose matrix V₀(k, n)^{H} of an N_{Tx}-row R-column sub-matrix V₀(k,n) of a unitary matrix (singular value decomposition processing step S4).

Next, the modulation signal generation unit 21 converts the test data to be transmitted to the UE 120 into a modulation signal in the frequency domain (modulation signal generation step S5).

Next, the beamforming processing unit 22 performs arithmetic processing equivalent to beamforming processing for achieving desired beam characteristics of the radio waves of the downlink signals transmitted from the N_{Tx} transmitting antennas Tx #1 to Tx #N_{Tx}, on the modulation signal in the frequency domain to generate N_{Tx} parallel beamforming processed signals (beamforming processing step S6).

Next, the integration unit 23 adds a CSI-RS as a test reference signal in the frequency domain to each of the N_{Tx} parallel beamforming processed signals, thereby generating N_{Tx} parallel test signals (addition step S7).

Next, the signal conversion unit 24 converts the N_{Tx} parallel test signals into R parallel signals by multiplying the N_{Tx} parallel test signals by V₀(k,n)^{H} (signal conversion step S8).

Next, the time-domain signal generation units 25-1 to 25-R perform inverse Fourier transform processing on the R parallel signals to generate OFDM modulation signals (time-domain signal generation step S9).

Next, the convolution operation unit 41 performs a convolution operation between the OFDM modulation signals generated in the time-domain signal generation step S9 and the impulse responses of the product U₀(k, n)D₀(k, n), generates N_{Rx} parallel test signals in the time domain that are respectively received by the N_{Rx} receiving antennas Rx #1 to Rx #N_{Rx} of the UE 120, and transmits the generated test signals to the UE 120 (convolution operation step S10).

As described above, the test system 1 according to the present embodiment performs singular value decomposition on the interpolated propagation path characteristics H(k,n), which include the instantaneous characteristics H(k, n_{RS}) of the propagation path characteristics obtained in the environment of the actual propagation path 110, into the form H(k,n)=U₀(k,n)D₀(k,n)V₀(k,n)^{H}, and applies V₀(k,n)^{H} in the frequency domain to the beamforming processed signal to which the CSI-RS is added.

This allows the test system 1 according to the present embodiment to simulate the propagation path environment while suppressing the circuit scale from the time-domain signal generation unit 25 onward, by using a method of reproducing the instantaneous characteristics of the propagation path characteristics of the actual propagation path 110.

Furthermore, since the test system 1 according to the present embodiment uses a method of reproducing the instantaneous characteristics of the propagation path characteristics of the actual propagation path 110, it is possible to simulate propagation path characteristics accompanied by the movement of the UE 120 and surrounding objects.

Furthermore, the test system 1 according to the present embodiment can obtain the effect of reducing the number of antennas in the frequency domain while keeping the effect of multipath and Doppler frequency shift in the time domain, with a simple configuration, by dividing the interpolated propagation path characteristics H(k,n) into V₀(k,n)^{H} and the product U₀(k, n)D₀(k, n), and performing processing in the frequency domain and time domain respectively.

Furthermore, the test system 1 according to the present embodiment can compress the data amount of V₀(k,n)^{H} and store the data in the propagation path characteristic storage unit 35, by converting the frequency domain V₀(k,n)^{H} data into an impulse response format.

Furthermore, the test system 1 according to the present embodiment can assure continuity between adjacent interpolated propagation path characteristics H(k,n) in the frequency axis and time axis by performing, as necessary, permutation of the singular values constituting the diagonal matrix D₀(k,n), permutation and phase adjustment of the column vectors constituting the sub-matrix U₀(k,n) of the unitary matrix, and permutation and phase adjustment of the column vectors constituting the sub-matrix V₀(k,n) of the unitary matrix.

Furthermore, the test system 1 according to the present embodiment can match the propagation path characteristics observed by the UE 120 when referencing the CSI-RS in a simulation environment with the propagation path characteristics observed by the antenna device 10 through the CSI-RS in the actual propagation path 110 environment, by performing a convolution operation while aligning the timing of the OFDM modulation signal including the CSI-RS with the impulse responses of the product U₀(k, n_{RS})D₀(k, n_{RS}) at the timing n_{RS} where the CSI-RS is included.

Moreover, the test system 1 according to the present embodiment can test the UE 120 by reproducing the interpolated propagation path characteristics H(k,n) and thereby reproducing the propagation path characteristics of the actual propagation path 110.

In the present embodiment described above, although the base station 100 is the network-side transceiver that transmits the downlink signal to the actual propagation path 110, for example, an access point of Wi-Fi (registered trademark) may be used as the network-side transceiver instead of the base station.

### DESCRIPTION OF REFERENCE NUMERALS AND SIGNS

1: Test system
10: Antenna device
11: IQ data output unit
20: Test device
21: Modulation signal generation unit
22: Beamforming processing unit
23: Integration unit
24: Signal conversion unit
25: Time-domain signal generation unit
26: Test signal generation unit
30: Propagation path characteristic acquisition unit
31: Actual propagation path characteristic calculation unit
32: Interpolation processing unit
33: Singular value decomposition processing unit
34: Impulse response calculation unit
35: Propagation path characteristic storage unit
40: Pseudo-propagation path
41: Convolution operation unit
100: Base station (network-side transceiver)
110: Actual propagation path
120: Device under test (UE)
Rx #1 to Rx #N_{Rx}: Receiving antenna
Tx #1 to Tx #N_{Tx}: Transmitting antenna

What is claimed is:

1. A test system that transmits test signals to a device under test having N_{Rx} receiving antennas, the test system comprising:
an actual propagation path characteristic calculation unit that calculates instantaneous characteristics H(k, n_{RS}) of propagation path characteristics of an actual propagation path for each subcarrier fₖ and timing t_{nRS}, using reference signals included in IQ data of a downlink signal output from an antenna device that receives the downlink signal transmitted from N_{Tx} transmitting antennas (Tx #1 to Tx #N_{Tx}) of a network-side transceiver at N_{Rx} receiving antennas (Rx #1 to Rx #N_{Rx}) in an actual propagation path environment;
a singular value decomposition processing unit that performs singular value decomposition on the instantaneous characteristics H(k, n_{RS}) into a form of H(k, n_{RS})=U₀(k, n_{RS})D₀(k, n_{RS})V₀(k, n_{RS})^{H}, and calculates an N_{Rx}-row R-column sub-matrix U₀ of a unitary matrix, an R-row R-column diagonal matrix D₀(k, n_{RS}) whose diagonal components are the effective singular values of the instantaneous characteristics H(k, n_{RS}), and a conjugate-transpose matrix V₀(k, n_{RS})^{H} of an N_{Tx}-row R-column sub-matrix V₀(k, n_{RS}) of a unitary matrix, where R is the number of effective singular values;
a test signal generation unit that generates a test reference signal transmitted from the N_{Tx} transmitting antennas, a modulation signal of test data to be transmitted to the device under test, and N_{Tx} parallel test signals including the test reference signal in the frequency domain and the modulation signal in the frequency domain;
a signal conversion unit that converts the N_{Tx} parallel test signals into R parallel signals by multiplying the N_{Tx} parallel test signals by the conjugate-transpose matrix V₀(k,n_{RS})^{H};
a time-domain signal generation unit that performs inverse Fourier transform processing on the R parallel signals to generate time-domain signals; and
a convolution operation unit that performs a convolution operation between the time-domain signals generated by the time-domain signal generation unit and impulse responses of a product U₀(k, n_{RS})D₀(k, n_{RS}) of the sub-matrix U₀(k, n_{RS}) of the unitary matrix and the diagonal matrix D₀(k, n_{RS}) to generate N_{Rx} parallel test signals in the time domain that are respectively received by the N_{Rx} receiving antennas of the device under test.

2. A test system that transmits test signals to a device under test having N_{Rx} receiving antennas, the test system comprising:
an actual propagation path characteristic calculation unit that calculates instantaneous characteristics H(k, n_{RS}) of propagation path characteristics of an actual propagation path for each subcarrier fₖ and timing t_{nRS}, using reference signals included in IQ data of a downlink signal output from an antenna device that receives the downlink signal transmitted from NrX transmitting antennas (Tx #1 to Tx #N_{Tx}) of a network-side transceiver at N_{Rx} receiving antennas (Rx #1 to Rx #N_{Rx}) in an actual propagation path environment;
an interpolation processing unit that interpolates the instantaneous characteristics H(k, n_{RS}) in a time axis direction to generate interpolated propagation path characteristics H(k,n) with a sampling rate that satisfies the sampling theorem;
a singular value decomposition processing unit that performs singular value decomposition on the interpolated propagation path characteristics H(k,n) into a form of H(k, n)=U₀(k, n)D₀(k, n) V₀(k, n)^{H}, and calculates an N_{Rx}-row R-column sub-matrix U₀ of a unitary matrix, an R-row R-column diagonal matrix D₀(k,n) whose diagonal components are the effective singular values of the interpolated propagation path characteristics H(k,n), and a conjugate-transpose matrix V₀(k,n)^{H} of an N_{Tx}-row R-column sub-matrix V₀(k,n) of a unitary matrix, where R is the number of effective singular values;
a test signal generation unit that generates a test reference signal transmitted from the N_{Tx} transmitting antennas, a modulation signal of test data to be transmitted to the device under test, and N_{Tx} parallel test signals including the test reference signal in the frequency domain and the modulation signal in the frequency domain;
a signal conversion unit that converts the N_{Tx} parallel test signals into R parallel signals by multiplying the N_{Tx} parallel test signals by the conjugate-transpose matrix V₀(k,n)^{H};
a time-domain signal generation unit that performs inverse Fourier transform processing on the R parallel signals to generate time-domain signals; and
a convolution operation unit that performs a convolution operation between the time-domain signals generated by the time-domain signal generation unit and impulse responses of a product U₀(k, n)D₀(k, n) of the sub-matrix U₀(k,n) of the unitary matrix and the diagonal matrix D₀(k,n) to generate N_{Rx} parallel test signals in the time domain that are respectively received by the N_{Rx} receiving antennas of the device under test.

3. The test system according to claim 1, wherein
the test signal generation unit includes
a modulation signal generation unit that generates the modulation signal in the frequency domain,
a beamforming processing unit that performs arithmetic processing equivalent to beamforming processing for achieving desired beam characteristics of radio waves of the downlink signal transmitted from the N_{Tx} transmitting antennas, on the modulation signal in the frequency domain to generate N_{Tx} parallel beamforming processed signals, and
an integration unit that adds the test reference signal in the frequency domain to each of the N_{Tx} parallel beamforming processed signals to generate the N_{Tx} parallel test signals.

4. The test system according to claim 2, wherein
the test signal generation unit includes
a modulation signal generation unit that generates the modulation signal in the frequency domain,
a beamforming processing unit that performs arithmetic processing equivalent to beamforming processing for achieving desired beam characteristics of radio waves of the downlink signal transmitted from the N_{Tx} transmitting antennas, on the modulation signal in the frequency domain to generate N_{Tx} parallel beamforming processed signals, and
an integration unit that adds the test reference signal in the frequency domain to each of the N_{Tx} parallel beamforming processed signals to generate the N_{Tx} parallel test signals.

5. The test system according to claim 2, further comprising:
a propagation path characteristic storage unit that stores impulse responses of the conjugate-transpose matrix V₀(k,n)^{H} and the impulse responses of the product U₀(k,n)D₀(k,n), wherein
the signal conversion unit, after performing a conversion to revert the impulse responses of the conjugate-transpose matrix V₀(k,n)^{H} read from the propagation path characteristic storage unit to the conjugate-transpose matrix V₀(k,n)^{H} in the frequency domain, multiplies the N_{Tx} parallel test signals by the conjugate-transpose matrix V₀(k,n)^{H} in the frequency domain, and
the convolution operation unit performs a convolution operation between the time-domain signals generated by the time-domain signal generation unit and the impulse responses of the product U₀(k, n)D₀(k, n) read from the propagation path characteristic storage unit.

6. The test system according to claim 2, wherein
the singular value decomposition processing unit performs permutation of the singular values constituting the diagonal matrix D₀(k,n), permutation and phase adjustment of column vectors constituting the sub-matrix U₀(k,n) of the unitary matrix, and permutation and phase adjustment of column vectors constituting the sub-matrix V₀(k,n) of the unitary matrix, such that elements of the product U₀(k, n)D₀(k, n) and elements of the column vectors constituting the sub-matrix V₀(k,n) of the unitary matrix continuously change between adjacent interpolated propagation path characteristics H(k,n) on a frequency axis and a time axis.

7. The test system according to claim 2, wherein
the convolution operation unit performs the convolution operation by aligning a timing of the time-domain signals including the test reference signal with a timing of the impulse responses of the product U₀(k,n)D₀(k,n) at a timing n_{RS} where the test reference signal is included.

8. A test method for transmitting test signals to a device under test having N_{Rx} receiving antennas, the test method comprising:
an actual propagation path characteristic calculation step (S2) of calculating instantaneous characteristics H(k, n_{RS}) of propagation path characteristics of an actual propagation path for each subcarrier fₖ and timing t_{nRS}, using reference signals included in IQ data of a downlink signal output from an antenna device that receives the downlink signal transmitted from N_{Tx} transmitting antennas (Tx #1 to Tx #N_{Tx}) of a network-side transceiver at N_{Rx} receiving antennas (Rx #1 to Rx #N_{Rx}) in an actual propagation path environment;
an interpolation processing step (S3) of interpolating the instantaneous characteristics H(k, n_{RS}) in a time axis direction to generate interpolated propagation path characteristics H(k,n) with a sampling rate that satisfies the sampling theorem;
a singular value decomposition processing step (S4) of performing singular value decomposition on the interpolated propagation path characteristics H(k,n) into a form of H(k, n)=U₀(k, n)D₀(k, n) V₀(k, n)^{H}, and calculating an N_{Rx}-row R-column sub-matrix U₀ of a unitary matrix, an R-row R-column diagonal matrix D₀(k,n) whose diagonal components are the effective singular values of the interpolated propagation path characteristics H(k,n), and a conjugate-transpose matrix V₀(k, n)^{H} of an N_{Tx}-row R-column sub-matrix V₀(k,n) of a unitary matrix, where R is the number of effective singular values;
steps (S5 to S7) of generating a test reference signal transmitted from the N_{Tx} transmitting antennas, a modulation signal of test data to be transmitted to the device under test, and N_{Tx} parallel test signals including the test reference signal in the frequency domain and the modulation signal in the frequency domain;
a signal conversion step (S8) of converting the N_{Tx} parallel test signals into R parallel signals by multiplying the N_{Tx} parallel test signals by the conjugate-transpose matrix V₀(k,n)^{H};
a time-domain signal generation step (S9) of performing inverse Fourier transform processing on the R parallel signals to generate time-domain signals; and
a convolution operation step (S10) of performing a convolution operation between the time-domain signals generated in the time-domain signal generation step and impulse responses of a product U₀(k, n)D₀(k, n) of the sub-matrix U₀(k,n) of the unitary matrix and the diagonal matrix D₀(k,n) to generate N_{Rx} parallel test signals in the time domain that are respectively received by the N_{Rx} receiving antennas of the device under test.
